(19) United States
(12) Patent Application Publication
(10) Pub. No.: US 2009/0321742 A1
(43) Pub. Date: Dec. 31, 2009

(54) THIN FILM TRANSISTOR

(75) Inventors: Yuan-Jun Hsu, Nantou County (TW); Ching-Chieh Shih, Kinmen County (TW); Kun-Chih Lin, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: AU OPTRONICS CORPORATION, Hsinchu (TW)

(21) Appl. No.: 12/272,813

(22) Filed: Nov. 18, 2008

(30) Foreign Application Priority Data
Jun. 27, 2008 (TW) 97124269

(51) Int. Cl. H01L 29/04

(52) U.S. Cl. 257/66; 257/E29.003

(57) ABSTRACT

A thin film transistor (TFT) including a substrate, a buffer layer, a patterned poly-silicon layer, a gate dielectric layer, and a number of gate electrodes is provided. The patterned poly-silicon layer is disposed on the buffer layer and the substrate. The patterned poly-silicon layer includes a number of channel regions, at least one heavily doped region, two lightly doped regions, a source region, and a drain region. The heavily doped region connects two adjacent channel regions. The source region connects one of the two outmost channel regions through one of the lightly doped regions. The drain region connects the other outmost channel region through the other lightly doped region. The gate dielectric layer covers the patterned poly-silicon layer. The gate electrodes are disposed on the gate dielectric layer and electrically connected to one another. Each gate is disposed above each channel region and a part of the heavily doped region.

### CROSS-REFERENCE TO RELATED APPLICATION

This application claims the priority benefit of Taiwan application serial no. 97124269, filed on Jun. 27, 2008. The entirety of the above-mentioned patent application is hereby incorporated by reference herein and made a part of this specification.

### BACKGROUND OF THE INVENTION

1. Field of the Invention

The present invention generally relates to a semiconductor device, and more particularly, to a thin film transistor (TFT).

2. Description of Related Art

Recently, with an advancement of optoelectronic and semiconductor technologies, flat panel displays have been vigorously developed. Among the flat panel displays, liquid crystal displays (LCDs) characterized by low operating voltage, no harmful radiation, light weight, and compactness have gradually replaced conventional CRT displays and become mainstream display products.

In general, the LCD can be categorized into an amorphous silicon TFT-LCD and a low temperature poly-silicon TFT-LCD. Compared with the amorphous silicon TFT, the low temperature poly-silicon TFT has a relatively high electron mobility (by two to three orders of magnitude, and therefore the poly-silicon TFT not only can serve as a switch of a pixel in a display region, but also can be applied in peripheral circuit regions as a circuit for driving the LCD.

Practically, the TFT acting as the switch of the pixel in the display region and the TFT acting as the driving circuit require different properties. The TFT serving as the switch of the pixel is normally required to achieve uniformity of electrical characteristics, while the TFT acting as the driving circuit should be characterized by high mobility of carriers and favorable reliability.

FIG. 1 is a schematic cross-sectional view of a conventional TFT. As depicted in FIG. 1, a TFT 100 is disposed on a substrate 101, and the TFT 100 includes a patterned poly-silicon layer 110 and two gate electrodes 130. A buffer layer 102 is disposed between the substrate 101 and the patterned poly-silicon layer 110. Through performing a doping process, a source region 112, a drain region 114, a heavily doped region 118H, four lightly doped regions 118L, and two channel regions 116 respectively are disposed below the two gate electrodes 130 and are formed in the patterned poly-silicon layer 110. Here, the two channel regions 116 are located between the source region 112 and the drain region 114. The heavily doped region 118H is disposed between the two channel regions 116, and two of the lightly doped regions 118L are disposed between the heavily doped region 118H and the two channel regions 116, respectively.

Referring to FIG. 1, a gate dielectric layer 120 covers the patterned poly-silicon layer 110 and the buffer layer 102, and the gate electrodes 130 are disposed on the gate dielectric layer 120 and corresponds the channel regions 116. A passivation layer 140 covers the gate electrodes 130 and the gate dielectric layer 120, and the passivation layer 140 and the gate dielectric layer 120 have an opening H exposing the source region 112 and the drain region 114. On the other hand, a source electrode 152 and a drain electrode 154 are disposed on the passivation layer 140 and are electrically connected to the source region 112 and the drain region 114 through the opening H, respectively.

Besides, when the TFT 100 acting as the switch of the pixel in the display region is switched on, a switch-on current of the TFT 100 is restrained due to the relatively low dopant concentration and high electrical resistance of lightly doped regions, thus posing a negative impact on electrical performance of the TFT 100.

### SUMMARY OF THE INVENTION

The present invention is directed to a TFT capable of enhancing reliability of devices and increasing a switch-on current.

A TFT including a substrate, a patterned poly-silicon layer, a gate dielectric layer, and a plurality of gate electrodes is provided in the present invention. The patterned poly-silicon layer is disposed on a buffer layer and includes a plurality of channel regions, at least one heavily doped region, two lightly doped regions, a source region, and a drain region. The heavily doped region is connected between two adjacent channel regions. The source region is connected to one of the two outmost channel regions through one of the lightly doped regions, while the drain region is connected to the other outmost channel region through the other lightly doped region. The gate dielectric layer covers the patterned poly-silicon layer. The gate electrodes are disposed on the gate dielectric layer and electrically connected to one another. Each of the gate electrodes is disposed above one of the channel regions and a part of the heavily doped region.

In an embodiment of the present invention, the number of the channel regions is N, the number of the heavily doped region is (N-1), and N is a positive integer greater than or equal to 2.

In an embodiment of the present invention, the TFT further includes the buffer layer disposed on the substrate. The patterned poly-silicon layer is disposed on the buffer layer.

In an embodiment of the present invention, the TFT further includes a passivation layer covering the gate dielectric layer and the gate electrodes. In an embodiment of the present invention, the TFT further includes a source electrode and a drain electrode that are disposed on the passivation layer. The passivation layer has a source contact opening and a drain contact opening. The source electrode is electrically connected to the source region through the source contact opening, while the drain electrode is electrically connected to the drain region through the drain contact opening.

In an embodiment of the present invention, the source region, the lightly doped regions, the channel regions, the heavily doped region, and the drain region are arranged along a straight trace. Extending directions of the gate electrodes can be parallel to one another.

In an embodiment of the present invention, the source region, the lightly doped regions, the channel regions, the heavily doped region, and the drain region are arranged along an L-shaped trace. Extending directions of the gate electrodes can be perpendicular to one another.

A TFT including a substrate, a patterned poly-silicon layer, and a plurality of gate electrodes is further provided in the present invention. The patterned poly-silicon layer is disposed on the substrate and includes a source region, a single first lightly doped region, a plurality of channel regions, a plurality of heavily doped regions, a single second lightly doped region, and a drain region. The heavily doped regions and the channel regions are alternately arranged. The gate electrodes are disposed on a gate oxide layer and arranged corresponding to the channel regions. The source region is connected to one of the two outmost channel regions through the single first lightly doped region, while the drain region is connected to the other outmost channel region through the single second lightly doped region.

In an embodiment of the present invention, the gate electrodes and the heavily doped regions are partially overlapped.

In an embodiment of the present invention, the gate electrodes are electrically connected to one another.

In an embodiment of the present invention, the TFT further includes a source electrode and a drain electrode. The source electrode is electrically connected to the source region, while the drain electrode is electrically connected to the drain region.

In an embodiment of the present invention, the source region, the single first lightly doped region, the heavily doped regions, the single second lightly doped region, and the drain region are all doped with an N-type dopant or a P-type dopant.

In an embodiment of the present invention, a dopant concentration of the source region, the heavily doped regions, or the drain region ranges from 2.0×10¹⁹ atom/cm³ to 2.0×10²¹ atom/cm³.

In an embodiment of the present invention, a dopant concentration of the single first lightly doped region or the single second lightly doped region is less than 5.0×10¹⁸ atom/cm³.

In an embodiment of the present invention, a dopant concentration of the single first lightly doped region or the single second lightly doped region and a dopant concentration of the source region, the heavily doped regions, or the drain region are different by one to three orders of magnitude.

In an embodiment of the present invention, the gate electrodes are not overlapped with the source region, the single first lightly doped region, the single second lightly doped region, or the drain region.

In an embodiment of the present invention, a dopant concentration of the source region, a dopant concentration of the heavily doped regions, and a dopant concentration of the drain region are equal.

In an embodiment of the present invention, a dopant concentration of the single first lightly doped region and a dopant concentration of the single second lightly doped region are equal.

Based on the above, no lightly doped region is disposed between two channel regions of the TFT in the present invention. Besides, a projection of the gate electrodes on the substrate is partially overlapped with that of the heavily doped regions. As such, the TFT of the present invention has a relatively favorable electrical reliability. Moreover, the switch-on current of the TFT can be increased while leakage current of the TFT can be reduced.

In order to make the aforementioned and other objectives, features, and advantages of the present invention be more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional TFT.

FIG. 2A is a top view of a TFT according to one embodiment of the present invention.

FIG. 2B is a schematic cross-sectional view of the TFT taken along a sectional line AA depicted in FIG. 2A.

FIG. 3 is a schematic view of a TFT according to one embodiment of the present invention.

FIG. 4 is a schematic view of a TFT according to one embodiment of the present invention.

FIG. 5A is a comparison diagram showing an electrical performance between a TFT according to one embodiment of the present invention and a conventional TFT.

FIG. 5B is a comparison diagram showing reliability between a TFT according to one embodiment of the present invention and a conventional TFT.

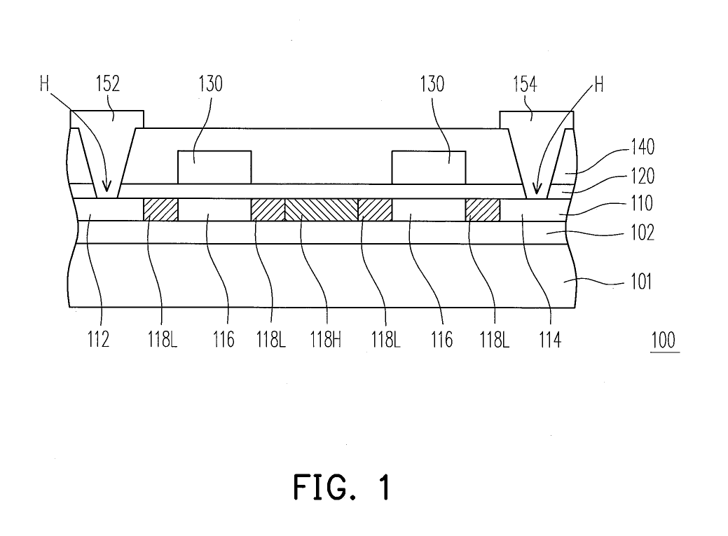

### DESCRIPTION OF EMBODIMENTS

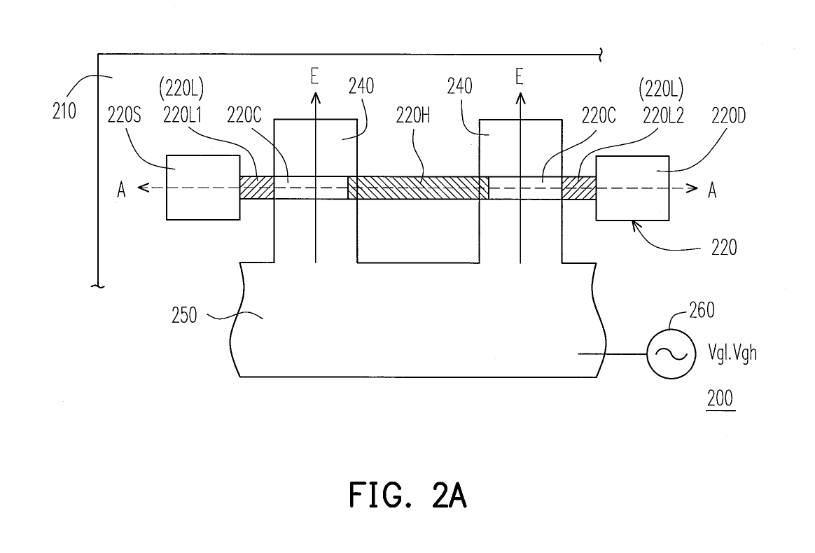

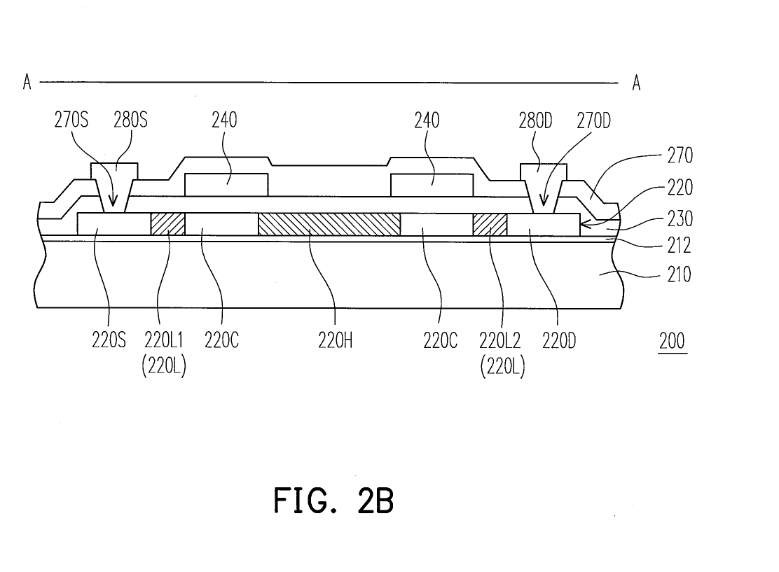

FIG. 2A illustrates a TFT according to one embodiment of the present invention. FIG. 2B is a schematic cross-sectional view of the TFT taken along a sectional line AA depicted in FIG. 2A. Referring to FIGS. 2A and 2B, a TFT 200 mainly includes a substrate 210, a patterned poly-silicon layer 220, a gate dielectric layer 230, and a plurality of gate electrodes 240. The patterned poly-silicon layer 220, the gate dielectric layer 230, and the gate electrodes 240 are all disposed on the substrate 210. As indicated in FIGS. 2A and 2B, the patterned poly-silicon layer 220 includes a plurality of channel regions 220C, at least one heavily doped region 220H, two lightly doped regions 220L, a source region 220S, and a drain region 220D. The heavily doped region 220H is connected between two adjacent channel regions 220C. The source region 220S is connected to one of the two outmost channel regions 220C through one of the lightly doped regions 220L (e.g., a first lightly doped region 220L1 shown in FIGS. 2A and 2B), while the drain region 220D is connected to the other outmost channel region 220C through the other lightly doped region 220L (e.g., a second lightly doped region 220L2 shown in FIGS. 2A and 2B). Each of the gate electrodes 240 is disposed above one of the channel regions 220C and a part of the heavily doped region 220H, and the gate electrodes 240 and the heavily doped region 220H are partially overlapped. In the present embodiment, the gate electrodes 240 are disposed above the channel regions 220C, such that the TFT 200 constitutes a top gate structure. However, in other embodiments, the gate electrodes 240 can be correspondingly disposed below the channel regions 220C, so as to form a bottom gate TFT 200, which is not limited in the present invention.

It should be mentioned that the difference between a conventional TFT and the TFT 200 of the present invention-lies in that no lightly doped region 220L is disposed between the heavily doped region 220H and the channel regions 220C in the TFT 200, and the gate electrodes 240 disposed above the channel regions 220 are extended above a part of the heavily doped region 220H. Hence, when the TFT 200 is in an on state, a switch-on current is increased. By contrast, when the TFT 200 is in an off state, leakage current is reduced. Thereby, reliability of the TFT 200 can be improved.

It is of certainty that the number of the gate electrodes 240, the number of the channel regions 220C, and the number of the heavily doped region 220H are not limited in the present invention. For instance, the heavily doped region 220H is interposed between two adjacent channel regions 220C. Therefore, when the number of the channel regions 220C is N, the number of the heavily doped region 220H is N-1, and N is equal to or greater than 2. In other words, at least two channel regions 220C are disposed in the TFT 200. Particularly, referring to FIGS. 2A and 2B, the TFT 200 of the present embodiment has a dual gate structure. One of the two lightly doped regions 220L (e.g., the first lightly doped region 220L1) is disposed between the heavily doped region 220H and the source region 220S, while the other lightly doped region 220L (e.g., the second lightly doped region 220L2) is disposed between the heavily doped region 220H and the drain region 220D. In other words, the number of the lightly doped region 220L between the heavily doped region 220H and the source region 220S is single one, and so is the number of the lightly doped region 220L between the heavily doped region 220H and the drain region 220D. As shown in FIGS. 2A and 2B, the lightly doped regions 220L, the channel regions 220C, the heavily doped region 220H, and the drain region 220D are arranged along a straight trace. That is to say, extending directions E of the gate electrodes 240 can be parallel to one another, which is not limited in the present invention and is determined upon actual demands and manufacturing conditions.

Specifically, an ion doping process can be carried out when the source region 220S, the drain region 220D, the channel regions 220C, the heavily doped region 220H, and the lightly doped regions 220L are defined. In detail, dopants with different concentrations can be used to perform a doping process on the patterned poly-silicon layer 220, so as to define the source region 220S, the drain region 220D, the channel regions 220C, the heavily doped region 220H, and the lightly doped regions 220L. In the present embodiment, the source region 220S, the first lightly doped region 220L1, the heavily doped region 220H, the second lightly doped region 220L2, and the drain region 220D are all doped with an N-type dopant or a P-type dopant. A dopant concentration of the source region 220S, the heavily doped region 220H, or the drain region 220D preferably ranges from 2.0×10¹⁹ atom/cm³ to 2.0×10²¹ atom/cm³. Besides, a dopant concentration of the first lightly doped region 220L1 or the second lightly doped region 220L2 is preferably less than 5.0×10¹⁸ atom/cm³. According to the present embodiment, the dopant concentrations of the source region 220S, the heavily doped region 220H, and the drain region 220D are equal, while the dopant concentrations of the first lightly doped region 220L1 and the second lightly doped region 220L2 are equal. The aforesaid dopant concentrations, however, do not limit the invention to said exemplary embodiment. Additionally, the dopant concentration of the first lightly doped region 220L1 or the second lightly doped region 220L2 is defined as a first concentration, while the dopant concentration of the source region 220S, the heavily doped region 220H, or the drain region 220D is defined as a second concentration. In the present embodiment, the first concentration and the second concentration can be different by one to three orders of magnitude, which are not limited in the present invention and are determined upon the actual demands and the manufacturing conditions.

Moreover, the gate electrodes 240 are electrically connected to one another. In particular, the gate electrodes 240 are often electrically connected to a gate signal source 260 through a scan line 250. Here, the gate signal source 260 is controlled by time sequence. Namely, a turned-on voltage level Vgh or a turned-off voltage level Vgl is selectively provided to the gate electrodes 240 in sequence, so as to determine the TFT 200 to be in the on state or in the off state. The gate electrodes 240 can be formed by implementing a sputtering process, an evaporation process, or other thin film deposition processes. In addition, the gate electrodes 240 can be made of aluminum (Al), molybdenum (Mo), titanium (Ti), neodymium (Nd), nitride of said metals (e.g., MoN or TiN), a stacked layer comprising said metals, an alloy of said metals, or other conductive materials. On the other hand, the gate dielectric layer 230 can be formed by chemical vapor deposition (CVD) or other appropriate thin film depositions, and the gate dielectric layer 230 can be made of dielectric materials, such as silicon oxide (SiOx), silicon nitride (SiNx), silicon oxynitride (SiON), high k material (high dielectric constant material), and so forth. The high k material has a permittivity higher than that of silicon dioxide (SiO₂) which is about 3.7.

Practically, referring to FIG. 2B, the TFT 200 can further include a buffer layer 212 disposed between the patterned poly-silicon layer 220 and the substrate 210, so as to enhance adhesion therebetween and to ensure electrical performance of the patterned poly-silicon layer 220 by preventing metallic ions (e.g., sodium ions) in the substrate 210 from diffusing to the patterned poly-silicon layer 220 or the gate dielectric layer 230. According to the present embodiment, the TFT 200 further includes a passivation layer 270 covering the gate dielectric layer 230 and the gate electrodes 240, so as to prevent the TFT 200 from being damaged by moisture. Here, the passivation layer 270 can be made of silicon nitride, silicon oxide, or an organic material. It is also likely to disposed a source electrode 280S and a drain electrode 280D on the passivation layer 270. Here, the passivation layer 270 has a source contact opening 270S and a drain contact opening 270D. The source electrode 280S is electrically connected to the source region 220S through the source contact opening 270S, while the drain electrode 280D is electrically connected to the drain region 220D through the drain contact opening 270D. The passivation layer 270 may also have a contact opening used for transmitting signals from the gate signal source 260 to the scan line 250.

As shown in FIGS. 2A and 2B, according to the present embodiment, the gate electrodes 240 may not be overlapped with the source region 220S, the first lightly doped region 220L1, the second lightly doped region 220L2, or the drain region 220D. Namely, edges of the gate electrodes 240 are respectively aligned to edges of the lightly doped regions 220L; however, it is not limited in the present invention. As such, the lightly doped region 220L1 adjacent to the source region 220S or the lightly doped region 220L2 adjacent to the drain region 220D is capable of avoiding a short channel effect. On the other hand, the gate electrodes 240 are extended above a part of the heavily doped region 220H, and therefore a controlling capacity of the gate electrodes 240 can be improved. As a result, when the TFT 200 of the present invention acts as a driving circuit which is similar to a shift register, the enhanced reliability of the TFT 200 can still be guaranteed after a long operation period or after the implementation of a reliability test.

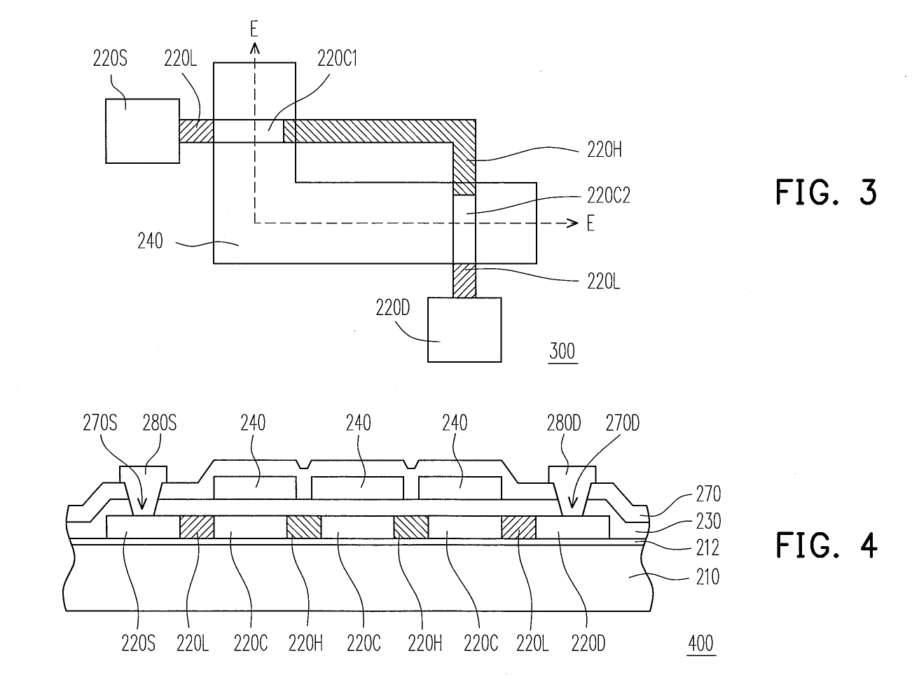

FIG. 3 is a schematic view of a TFT according to one embodiment of the present invention. Referring to FIG. 3, in consideration of layout space, aperture ratios, or the like, the source region 220S, the lightly doped regions 220L, the channel regions 220C, the heavily doped region 220H, and the drain region 220D in a TFT 300 can also be arranged in an L-shaped trace, and the extending directions E of the gate electrodes 240 can be perpendicular to one another. As indicated in FIG. 3, the lightly doped regions 220L are merely disposed between the source region 220S and a channel region 220C1 and between the drain region 220D and a channel region 220C2, respectively, and therefore a relatively high lateral electric field in the adjacent source region 220S and the drain region 220D can be reduced. In addition, no lightly doped region 220L is disposed between the heavily doped region 220H and the channel regions 220C (e.g., the channel regions 220C1 and 220C2 in FIG. 3), and thus the TFT 300 is likely to have a relatively high switch-on current when the TFT 300 is in an on state.

Note that the number of the gate electrodes 240 in the previous embodiment is two; however, it is not limited in the present invention. The number of the gate electrodes 240 can be three or more based on electrical demands of the TFT. For example, please refer to FIG. 4 which is a schematic view of a TFT according to one embodiment of the present invention. As shown in FIG. 4, N is equal to 3 in the present embodiment. That is to say, the number of the gate electrodes 240 and the number of the channel regions 220C in a TFT 400 are three, respectively. The number of the heavily doped regions 220H is 2, and so is the number of the lightly doped regions 220L (e.g. the first lightly doped region 220L1 adjacent to the source region 220S and the second lightly doped region 220L2 adjacent to the drain region 220D). Besides, a projection of the gate electrodes 240 on the substrate 210 may not be overlapped with that of the lightly doped regions 220L, while a projection of the gate electrodes 240 is required to be partially overlapped with that of the heavily doped regions 220H.

In other words, different from the conventional TFT, no lightly doped region 220L is disposed between the heavily doped regions 220H and the channel regions 220C, between the heavily doped regions, and between the channel regions 220C in the TFT 400 of the present invention. Additionally, the gate electrodes 240 disposed above the channel regions 220C are extended above a part of the heavily doped regions 220H. As such, the TFT 400 not only can reduce the leakage current but also can increase the switch-on current. Some measured data are provided below to elaborate the electrical performance of the TFT.

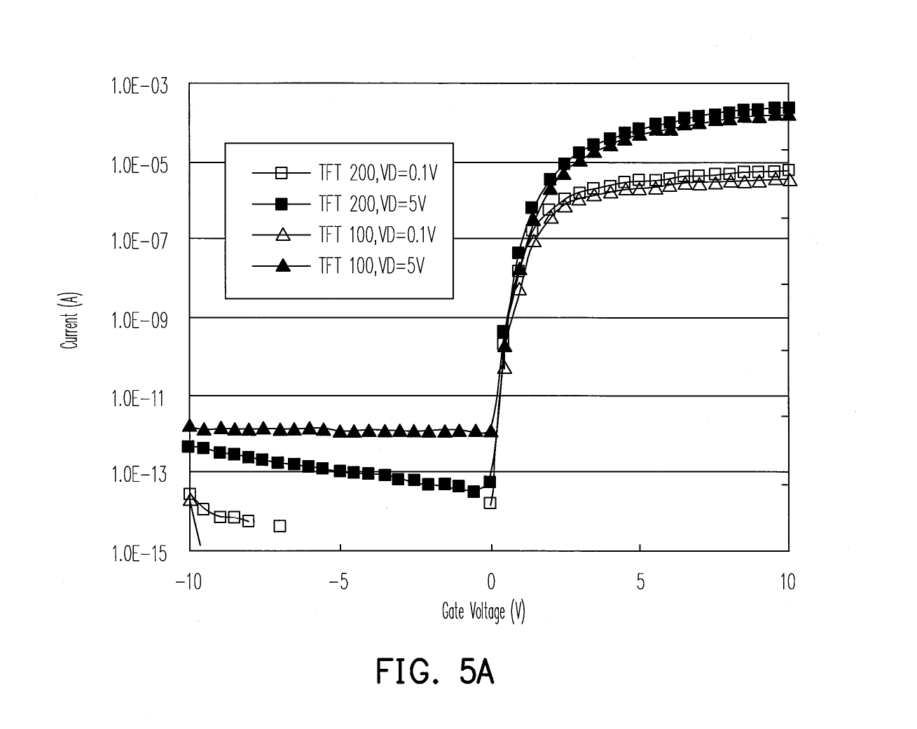

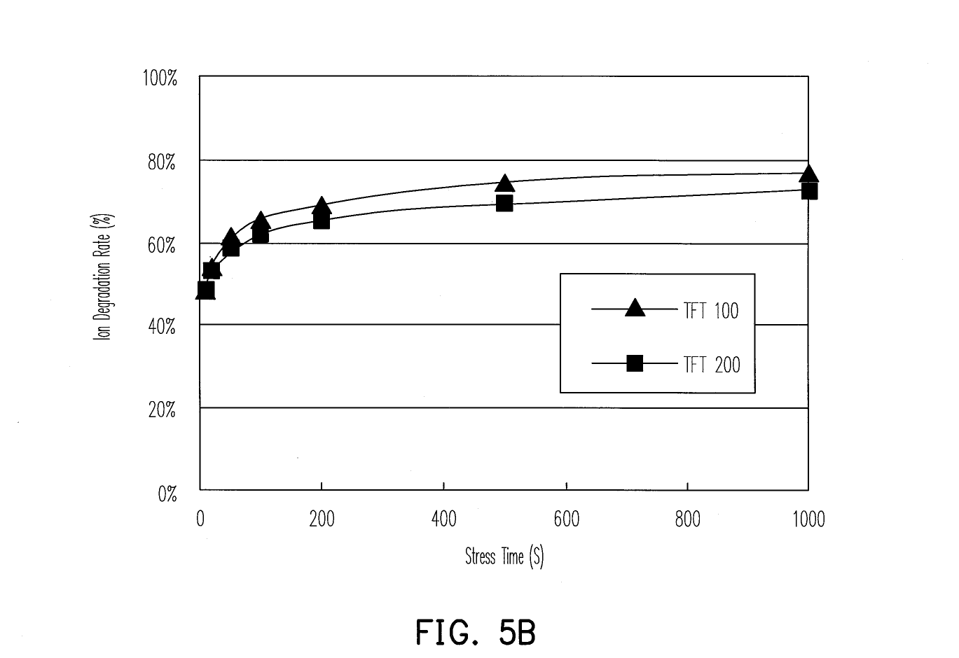

FIG. 5A is a current-voltage (I-V) diagram of a TFT according to one embodiment of the present invention. Referring to FIG. 5A, transfer characteristics of the conventional TFT 100 and the TFT 200 are provided in a form of comparison curves. It can be observed from FIG. 5A that the TFT 200 of the present invention has a relatively low leakage current and a high switch-on current in comparison with the conventional TFT 100.

FIG. 5B shows reliability of a TFT according to one embodiment of the present invention. Referring to FIG. 5B, an on-current degradation rate, which labeled as Iₒₙ degradation rate, comparison diagram of the conventional TFT 100 and the TFT 200 after the implementation of the reliability test is provided. It can be learned from FIG. 5B that the TFT 200 of the present invention has a stable Iₒₙ degradation rate which is not apt to be degraded in comparison with the conventional TFT 100 after the implementation of the reliability test or after a long operation period. As such, the TFT 200 of the present invention is characterized by a relatively favorable device reliability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a substrate;
a patterned poly-silicon layer, disposed on the substrate and comprising a plurality of channel regions, at least one heavily doped region, two lightly doped regions, a source region, and a drain region, wherein the heavily doped region is connected between two adjacent channel regions, the source region is connected to one of the two outmost channel regions through one of the lightly doped regions, and the drain region is connected to the other outmost channel region through the other lightly doped region;
a gate dielectric layer, covering the patterned poly-silicon layer; and
a plurality of gate electrodes disposed on the gate dielectric layer and electrically connected to one another, wherein each of the gate electrodes is disposed above one of the channel regions and a part of the heavily doped region.

2. The thin film transistor as claimed in claim 1, wherein the number of the channel regions is N, the number of the heavily doped region is (N-1), and N is a positive integer greater than or equal to 2.

3. The thin film transistor as claimed in claim 1, further comprising a buffer layer disposed on the substrate, the patterned poly-silicon layer being disposed on the buffer layer.

4. The thin film transistor according to claim 1, further comprising a passivation layer covering the gate dielectric layer and the gate electrodes.

5. The thin film transistor as claimed in claim 4, further comprising:
a source electrode disposed on the passivation layer; and
a drain electrode disposed on the passivation layer, wherein the passivation layer has a source contact opening and a drain contact opening, the source electrode is electrically connected to the source region through the source contact opening, and the drain electrode is electrically connected to the drain region through the drain contact opening.

6. The thin film transistor as claimed in claim 1, wherein the source region, the lightly doped regions, the channel regions, the heavily doped region, and the drain region are arranged along a straight trace.

7. The thin film transistor as claimed in claim 1, wherein extending directions of the gate electrodes are parallel to one another.

8. The thin film transistor as claimed in claim 1, wherein the source region, the lightly doped regions, the channel regions, the heavily doped region, and the drain region are arranged along an L-shaped trace.

9. The thin film transistor as claimed in claim 1, wherein extending directions of the gate electrodes are perpendicular to one another.

10. A thin film transistor, comprising:
a substrate;
a patterned poly-silicon layer, disposed on the substrate, comprising a source region, a single first lightly doped region, a plurality of channel regions, a plurality of heavily doped regions, a single second lightly doped region, and a drain region, wherein the heavily doped regions and the channel regions are alternately arranged; and
a plurality of gate electrodes disposed on the substrate and respectively arranged corresponding to the channel regions, wherein the source region is connected to one of the two outmost channel regions through the single first lightly doped region, and the drain region is connected to the other outmost channel region through the single second lightly doped region.

11. The thin film transistor as claimed in claim 10, wherein the gate electrodes and the heavily doped regions are partially overlapped.

12. The thin film transistor as claimed in claim 10, wherein the gate electrodes are electrically connected to one another.

13. The thin film transistor as claimed in claim 10, further comprising a source electrode and a drain electrode, wherein the source electrode is electrically connected to the source region, and the drain electrode is electrically connected to the drain region.

14. The thin film transistor as claimed in claim 10, wherein the source region, the single first lightly doped region, the heavily doped regions, the single second lightly doped region, and the drain region are all doped with an N-type dopant or a P-type dopant.

15. The thin film transistor as claimed in claim 10, wherein a dopant concentration of the source region, the heavily doped regions, or the drain region ranges from 2.0×10¹⁹ atom/cm³ to 2.0×10²¹ atom/cm³.

16. The thin film transistor as claimed in claim 10, wherein a dopant concentration of the single first lightly doped region or the single second lightly doped region is less than 5.0×10⁸ atom/cm³.

17. The thin film transistor as claimed in claim 10, wherein a dopant concentration of the single first lightly doped region or the single second lightly doped region and a dopant concentration of the source region, the heavily doped regions, or the drain region are different by one to three orders of magnitude.

18. The thin film transistor as claimed in claim 10, wherein the gate electrodes are not overlapped with the source region, the single first lightly doped region, the single second lightly doped region, or the drain region.

19. The thin film transistor as claimed in claim 10, wherein a dopant concentration of the source region, a dopant concentration of the heavily doped regions, and a dopant concentration of the drain region are equal.

20. The thin film transistor as claimed in claim 10, wherein a dopant concentration of the single first lightly doped region and a dopant concentration of the single second lightly doped region are equal.
